(19) United States
(12) Patent Application Publication
(10) Pub. No.: US 2007/0235877 A1
(43) Pub. Date: Oct. 11, 2007

(54) Integration scheme for semiconductor photodetectors on an integrated circuit chip

(76) Inventors: Miriam Reshotko, Portland, OR (US); Bruce Block, Portland, OR (US); David Kencke, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/394,818

(22) Filed: Mar. 31, 2006

(51) Int. Cl. H01L 23/52

(52) U.S. Cl. 257/758

(57) ABSTRACT

A semiconductor device is described with a photodetector embedded within and a method of manufacturing the same. The photodetector may be formed above the conductive layers within the device and may detect transmitted light from the top side of the device. The process of manufacturing the device may include a damascene or a subtractive etch process.

### FIELD

Embodiments of the invention relate generally to semiconductor processing, and, more specifically, to an integration scheme for semiconductor photodetectors on an integrated circuit chip.

### BACKGROUND

In order to integrate photodetectors with circuit chips, photodetectors are generally grown separately on separate substrates, and then connected by flip chip bonding (to bumps), wire-bonding, or some other package solution. Alternatively, where photodetectors have been integrated with circuitry, there are generally only one or two layers of metal, and the photodetector material is generally grown either directly on the semiconductor substrate beneath the interlayer dielectric material and layers metallization, or by forming a trench through the metallization layers and using lateral overgrowth.

### BRIEF DESCRIPTION OF THE DRAWINGS

The present invention is illustrated by way of example and not limitation in the figures of the accompanying drawings, in which like references indicate similar elements, and in which:

FIG. 1 is a cross-sectional illustration of a photodetector disposed on a dielectric material and embedded within a semiconductor device according to an embodiment of the present invention.

FIG. 2 is a cross-sectional illustration of multiple photodetectors embedded within a semiconductor device according to an embodiment of the present invention.

FIG. 3 is a flowchart of two methods of forming embodiments of the present invention.

FIG. 4A-4E is a method of forming a semiconductor device with a photodetector embedded within, which includes a subtractive etch process according to an embodiment of the present invention.

FIG. 5A-5I is a method of forming a semiconductor device with a photodetector embedded within, which includes a damascene process according to an embodiment of the present invention.

### DETAILED DESCRIPTION

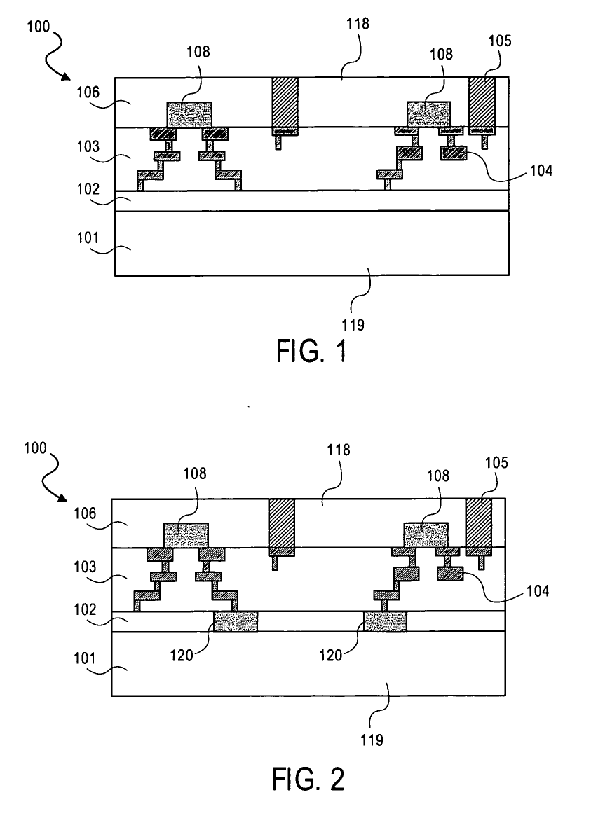

FIG. 1 is an illustration of a device 100 according to one embodiment of the present invention. Device 100 may be a microprocessor, memory (SRAM or DRAM), or any other semiconductor device. As illustrated, device 100 includes features: substrate 101, front end device region 102, dielectric layers 103, 106, conductive and interconnect layers 104, and contacts 105. Substrate 101 may comprise silicon, silicon on insulator, gallium arsenide, or any semiconductor material from which an integrated circuit can be formed. Front end device region 102 may include transistors, isolation structures, metal contacts, or other device features which are coupled to conductive and interconnects layers 104 and contacts 105 to facilitate 1/O for device 100. Dielectric layers 103, 106 may comprise any material that is not electrically conductive such that portions of conductive layers 104 are electrically isolated. In an embodiment, dielectric layers 103, 106 comprise silicon dioxide. Device 100 may comprise multiple conductive layers and corresponding dielectric layers. For example, device 100 may comprise greater than six conductive layers and greater than six dielectric layers. Only two dielectric layers, dielectric layers 103, 106, are illustrated in FIG. 1 for simplicity and convenience. However, while dielectric layers 103, 106 are illustrated as single layers, dielectric layers 103, 106 may include multiple layers. Furthermore, even though dielectric layers 103, 106 are referred to as single layers herein, the term encompasses embodiments with multiple layers of dielectric material making up dielectric layers 103, 106.

In an embodiment, device 100 comprises seven conductive layers 104 and seven dielectric layers to electrically isolate each conductive layer 104.

As further illustrated in FIG. 1, a photodetector 108 may be formed over second dielectric layer 106. Photodetector 108 may function within device 100 to generate an electrical signal from a received optical signal, and transmit the electrical signal to conductive and interconnect layers 104. Photodetector 108 may detect light transmitted to device 100 from a backside 119 or front side 118 of device 100. In an embodiment, photodetector 108 detects light transmitted to the backside 119 of device 100.

Photodetector 108 may have a variety of shapes and sizes. For example, photodetector 108 may have a substantially square or rectangular cross-sectional shape and in the embodiment of FIG. 1, photodetector 108 may have a substantially cross-sectional rectangular shape. Photodetector 108 may extend as far laterally and as high vertically above first dielectric layer 103 as needed to capture light transmitted to device 100. For example, the cross-sectional width of photodetector 108 may range from 0.5 μm to 100 μm and the cross-sectional thickness of photodetector 108 may range from 0.1 μm to 1 μm. In an embodiment, the cross-sectional width and thickness of photodetector 108 may be approximately 5 μm and 0.5 μm respectively.

Device 100 may also contain a photodetector 120 disposed within substrate 100 and adjacent to front end device region 102 as illustrated in FIG. 2. In an embodiment, photodetector 120 may function similarly to photodetector 108 to facilitate I/O for device 100. Photodetector 120 may capture light transmitted from the front side 118 of device 100 or the backside 119 of device 100. In an embodiment, photodetector 120 captures light from the front side 118 of device 100, generates an electrical signal from the received light, and transmits the electrical signal to the front end device region 102. In other embodiments, photodetector 120 absorbs light from the backside 119 of device 100, generates an electrical signal from the received light, and transmits the electrical signal to the front end region 102 via conductive and interconnect layers 104.

A photodetector of the present invention may comprise any material capable of receiving light and in response, generate an electrical signal. For example, photodetectors 108, 120 may comprise silicon, silicon-germanium, germanium or other semiconductor materials such as gallium arsenide or indium phosphide. In an embodiment, photodetectors 108, 120 may comprise germanium, which has shown excellent absorption at commercial wavelengths used for long-haul and short-haul optical interconnects.

Accordingly, photodetectors 108, 120 may absorb light with wavelengths in the range of 400 nm to 1700 nm. Photodetector 108 may be able to absorb or receive light with shorter wavelengths than that of photodetector 120 when light is transmitted to the frontside 118 of device 100 because the light transmitted may not be impeded by stacks of conductive layers. For example, photodetector 108 may absorb light with wavelengths in the range from 400 nm to 1700 nm and photodetector 120 may absorb light with wavelengths in the range from 1100 nm to 1700 nm since the light may be excited through the substrate. In an embodiment, photodetectors 108, 120 may detect light with a wavelength of 1310 nm.

Device 100 may contain multiple photodetectors embedded within as illustrated in FIG. 2. For example, device 100 may contain a photodetector 108 disposed over first dielectric layer 103 and/or a photodetector 120 disposed within substrate 101. For example, device 100 may contain a range from 10 to 10,000 photodetectors disposed within substrate 101 and/or on first dielectric layer 103. In an embodiment, device 100 contains 1024 photodetectors 108 disposed above the conductive and interconnect layers in device 100; each photodetector 108 may be associated with one on-chip or chip-to-chip optical interconnect link.

Dielectric layers 103, 106 may affect photodetectors' 108, 120 ability to transmit light within device 100. For example, the thickness of second dielectric layer 106 may affect the quantity of light detected by photodetector 108 transmitted through the backside 118 of device 100. Also, the combined thickness of dielectric layers 103, 106 may affect the amount of light detected by photodetector 120 transmitted through the backside 118 of device 100. The thickness of dielectric layers 103, 106 may range from 0.1 μm to 1 μm and 0.2 μm to 2 μm respectively and in an embodiment, the thickness of dielectric layers 103, 106 may be approximately 0.5 μm and 1 μm respectively.

The index of refraction of dielectric layers 103, 106 may also affect the amount of light received by the photodetectors within device 100. The index of refraction of dielectric layers 103, 106 may range from 1.2 to 2.2 in order to maximize the amount of light received by the photodetectors within device 100 since the indices and thicknesses may be chosen so as to comprise an antireflective coating for the wavelength of interest. In an embodiment, dielectric layers 103, 106 may have an index of refraction equal to 1.5 and 1.5 respectively.

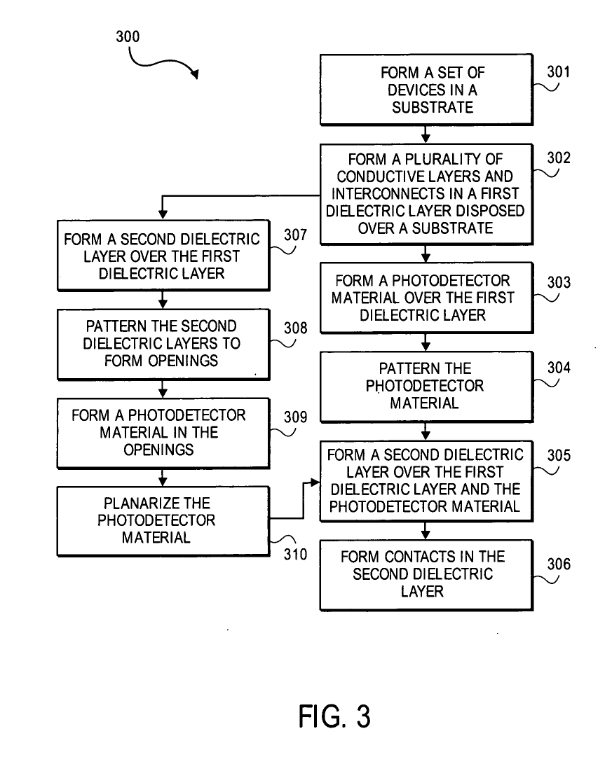

In an embodiment of the present invention, device 100 may be manufactured by any suitable process such that photodetector 108 may be disposed over first dielectric layer 103. In an embodiment as illustrated in FIG. 3, device 100 may be formed by one of the two processes recited in flowchart 300. The first process may be defined in flowchart 300 as including steps 301, 302, 303, 304, 305, and 306 and a second process may be defined as including steps 301, 302, 307, 308, 309, and 310.

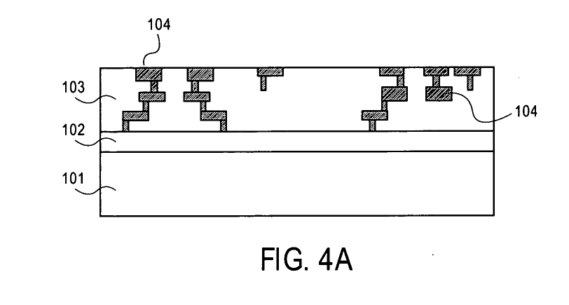

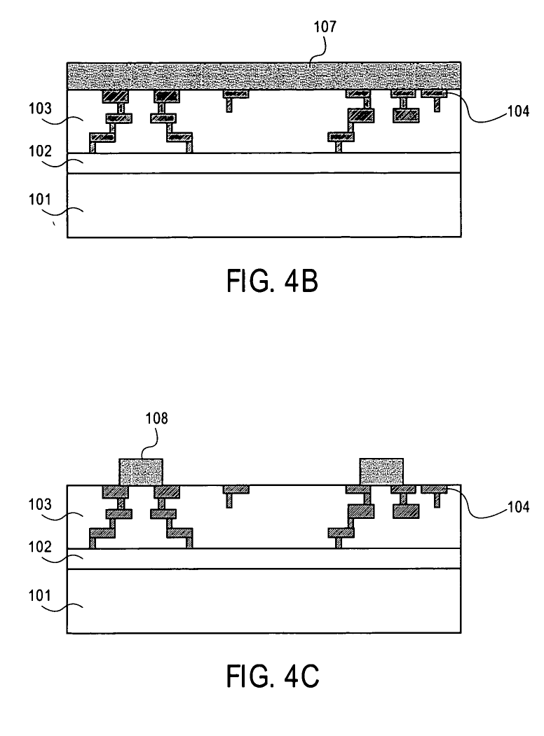

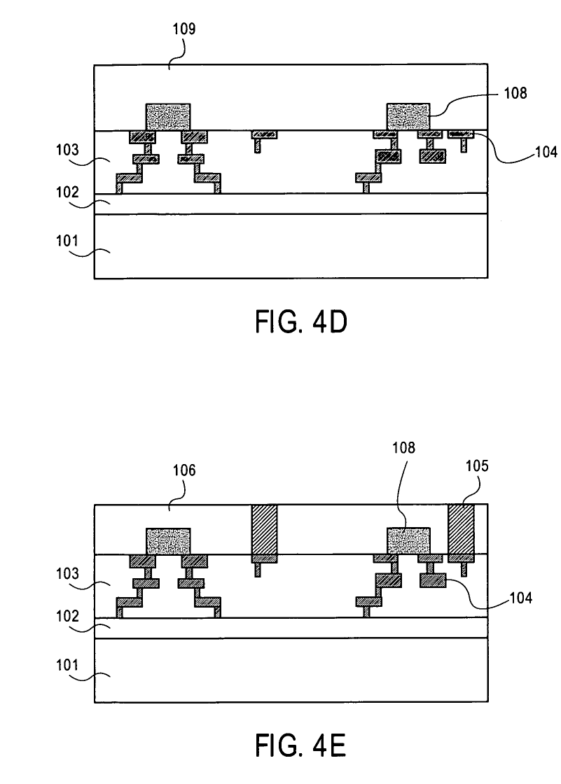

In an embodiment as illustrated in FIGS. 4A-4E, device 100 may be manufactured according to the first process defined in flowchart 300. FIG. 4A illustrates the beginning of the first process defined in flowchart 300. As illustrated, substrate 101 is provided comprising front end device region 102 disposed above. In an embodiment, front end device region may include a combination of transistors, isolation structures and metal contacts. The device features in front end device region 102 may be formed by a plurality of semiconductor process methods including oxidation, chemical vapor deposition, etch, implantation, and photolithography. FIG. 4A further illustrates first dielectric layer 103, which may comprise silicon dioxide or any dielectric material capable of isolating electrically conductive material. In an embodiment, device 100 comprises greater than six dielectric layers to electrically isolate each subsequently formed conductive layers. In an embodiment, the layer or layers that make up the first dielectric layer 103 may be formed by a deposition process such as, but not limited to, chemical vapor deposition (CVD), plasma enhanced chemical vapor deposition (PECVD), or high density plasma chemical vapor deposition (HDP CVD). Disposed within first dielectric layer 103 are conductive and interconnect layers 104 according to an embodiment. Conductive layers and interconnects 104, although disposed within first dielectric layer 103, are electrically coupled to devices in front end device region 102.

Next, in an embodiment, a photodetector material 107 may be formed over first dielectric layer 103 as illustrated in FIG. 4B. Photodetector material 107 may be formed by any suitable method known in the art. For example, photodetector material 108 may be formed by chemical vapor deposition or a sputtering process. In an embodiment, a chemical vapor deposition process may be used to form 5000 A of germanium on first dielectric layer 103.

Photodetector material 107 may be patterned by methods known in the art to form photodetector 108. Photodetector material 107 may be patterned by a combination of lithography and etch processes. As illustrated in FIG. 4C, a plurality of photodetector 108 mesas are formed after a series of lithography and etch processes.

Subsequently, a second dielectric layer 106 may be formed over photodetector 108 and the top surface of first dielectric layer 103 as illustrated in FIG. 4D. Second dielectric layer 106 may be formed by any suitable method known in the art, such as, but not limited to chemical vapor deposition (CVD), high density plasma chemical vapor deposition (HPCVD), or plasma enhanced chemical vapor deposition (PECVD). In an embodiment, a CVD process may be used to form 1 μm of silicon dioxide over photodetector 108 and the top surface of first dielectric layer 103.

Next, contacts 105 may be formed in second dielectric layer 106 as illustrated in FIG. 4E. As stated previously, a plurality of dielectric layers are formed in device 100 to electrically isolate layers of conductivity, but only two dielectric layers are shown for illustrative simplicity. Contacts 105 may be formed by a variety of methods known in the art. In an embodiment, contacts 105 may be formed by first etching an opening in second dielectric layer 106, forming a conductive material in the opening, and planarizing the conductive material to the top surface of second dielectric layer 106.

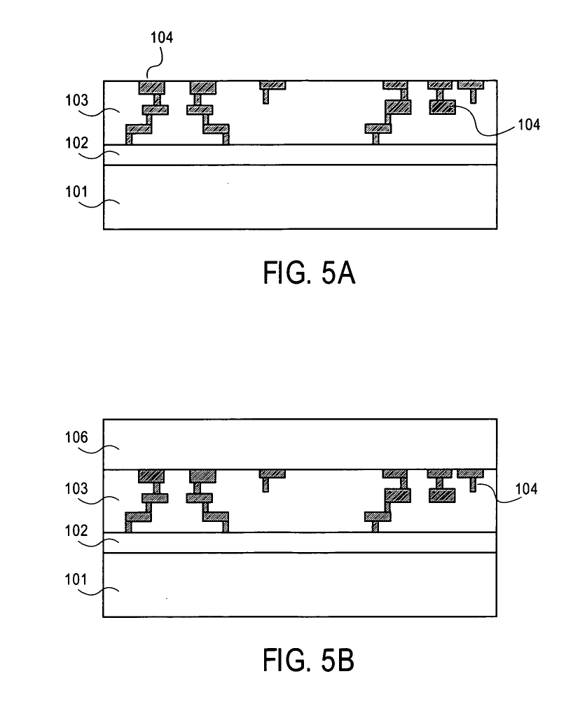

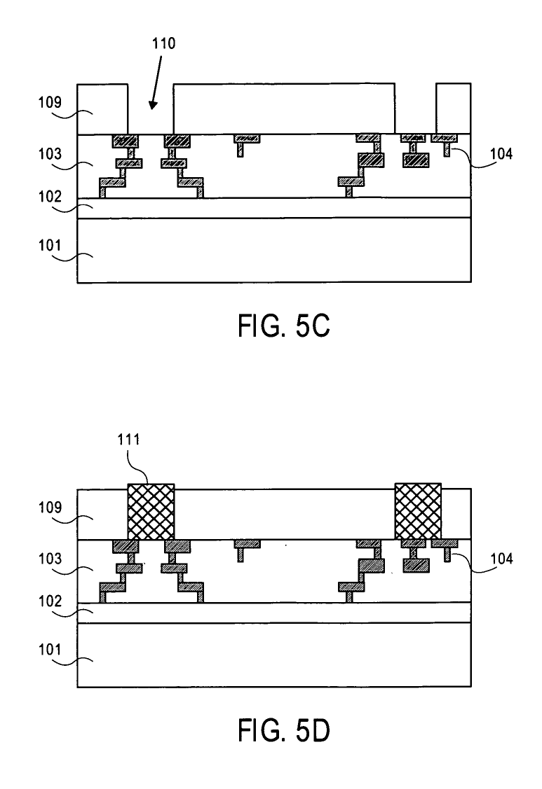

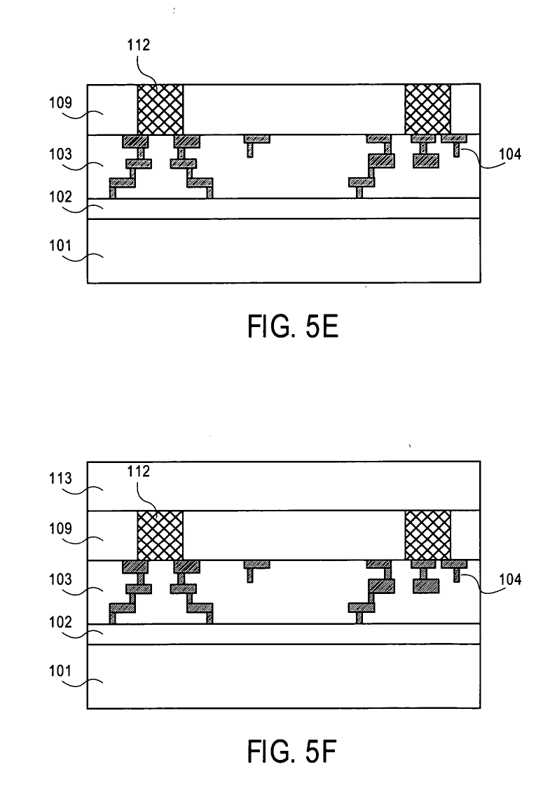

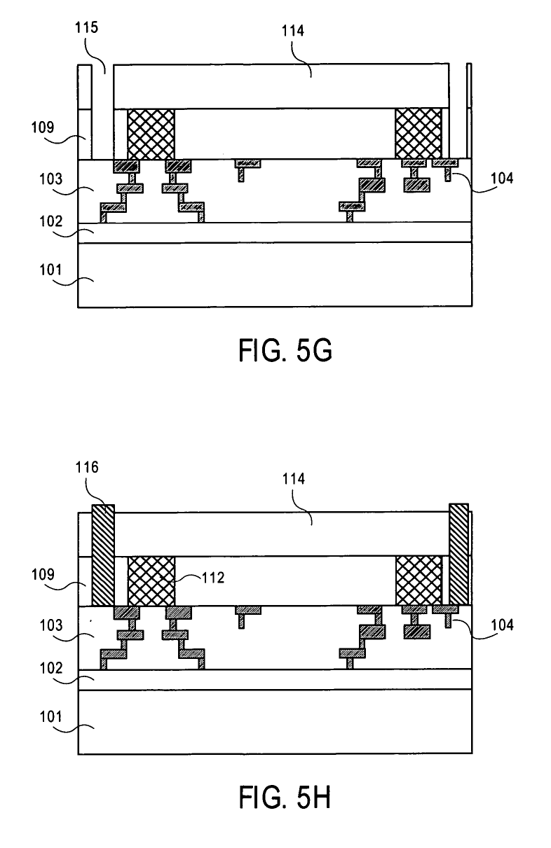

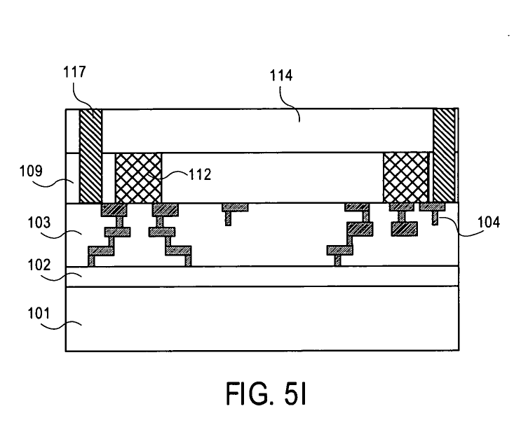

Device 100 may also be manufactured by a second process defined in flowchart 300 as illustrated in FIGS. 5A-5I. FIG. 5A illustrates the beginning of the second process defined in flowchart 300. Similarly to the first process defined in flowchart 300, FIG. 5A illustrates a substrate 101 with front end device region 102 disposed above, and a first dielectric layer 103 disposed above the front end device region 102. Front end device region 102 may include a combination of transistors, isolation structures, and metal contacts formed by any suitable method known in the art.

A second dielectric layer 106 may be formed over first dielectric layer 103 as illustrated in FIG. 5B. As mentioned previously in the first process, second dielectric layer 106 may be formed by any suitable method known in the art.

After second dielectric layer 106 is formed over first dielectric layer 103, openings 110 may be formed within second dielectric layer 106, forming patterned second dielectric layer 109 as illustrated in FIG. 5C. Opening 110 may have a width in the range from 0.5 μm to 100 μm and a depth in the range from 0.1 μm to 1 μm and in an embodiment, opening 110 may have a width and depth of 5 μm and 0.5 μm respectively.

Next, according to the embodiment illustrated in FIG. 5D, a photodetector material 111 may be formed in opening 110. Photodetector material 111 may be formed by any suitable process known in the art, such as, but not limited to, sputtering, evaporation, or chemical vapor deposition and in an embodiment, photodetector material 111 may be formed by a chemical vapor deposition process. After forming photodetector material 111 within opening 110, photodetector material 111 may be planarized such that the top surface of photodetector material 111 may be level with the top surface of patterned second dielectric layer 109 as illustrated by planarized photodetector 112 in FIG. 5E. In an embodiment, photodetector material 111 may be planarized by a chemical mechanical polishing (CMP) method.

A third dielectric layer 113 may be formed over patterned second dielectric layer 109 and planarized photodetector 112 in preparation of forming contacts 116 as illustrated in FIG. 5F. Third dielectric layer 113 may be formed by methods similar to the formation of first and second dielectric layers 103, 109. In an embodiment, third dielectric layer 113 may be formed by a CVD process. As stated previously, a plurality of dielectric layers are formed in device 100 to electrically isolate layers of conductivity, but only two dielectric layers are shown for illustrative simplicity. In an embodiment, greater than six dielectric layers are formed in device 100 to electrically isolate six or more conductive layers.

Subsequently in an embodiment, an opening 115 may be formed in third dielectric layer 113 as illustrated in FIG. 5G in anticipation of contact formation. Opening 115 may be formed by methods similar to that of forming opening 110 described above.

After forming opening 115, a conductive material may be formed within to form contacts 116 as illustrated in FIG. 5H. Contacts 116 may be formed in a similar method to the formation of photodetector material 111. In an embodiment, conductive material 116 may be formed in opening 115 by a damascene process. Once formed in opening 115, conductive material 116 may be planarized by a chemical mechanical polish (CMP) and the resulting structure of conductive material 116 may appear as illustrated in FIG. 5I.

An alternate method of coupling a semiconductor device having a photodetector formed within includes receiving a light and generating an electrical signal in response to the received light. The photodetector is disposed on a first dielectric material and a second dielectric material is disposed on the photodetector. The method further includes transmitting the electrical signal to the front end devices through a plurality of conductive layers disposed within the semiconductor device. The electrical signal is generated as the received light creates free electrons in the photodetector and a potential is applied to the photodetector which causes current to flow to the plurality of conductive layers.

In the foregoing specification, specific exemplary embodiments of the invention have been described. It will, however, be evident that various modifications and changes may be made thereto. The specification and drawings are, accordingly, to be regarded in an illustrative rather than a restrictive sense.

What is claimed is:

1. A device comprising:
a substrate;
a set of front end devices disposed in said substrate;
a set of first dielectric layers disposed over said set of front end devices;
a set of conductive layers embedded in said set of first dielectric layers, wherein said set of conductive layers comprises greater than or equal to six conductive layers; and
a first photodetector disposed over said first dielectric layer.

2. The device of claim 1, wherein said set of first dielectric layers comprise silicon dioxide.

3. The device of claim 1, wherein said set of conductive layers comprises seven conductive layers.

4. The device of claim 1, wherein said first photodetector absorbs light directed through the front side of said substrate.

5. The device of claim 1 further comprises a second photodetector disposed on said substrate and adjacent to said front end devices.

6. The device of claim 1, wherein said first photodetector pattern comprises germanium.

7. The device of claim 1, wherein said set of first dielectric layers has a low index of refraction.

8. A device comprising:
a substrate;
a device layer with a plurality of transistors;
a region of dielectric layers disposed over said device layer;
a plurality of conductive layers embedded within said region of dielectric layers; and
a photodetector disposed over said region of dielectric layers.

9. The device of claim 8, wherein said photodetector is coupled to said plurality of conductive layers.

10. The device of claim 8, wherein said photodetector absorbs light with a wavelength less than 1000 nanometers.

11. The device of claim 8, wherein said plurality of conductive layers comprises greater than six metal layers.

12. The device of claim 8, wherein the thickness of said region of dielectric layers is greater than one micron.

13. A method comprising:
forming a plurality of devices on a substrate;
forming a region of dielectric layers on said substrate;
forming a plurality of conductivity layers and interconnects in said region of dielectric layers; and
forming a photodetector over said region of dielectric layers.

14. The method of claim 13 further comprises:
forming a first dielectric layer over said first photodetector;
planarizing said first dielectric layer; and
forming contacts in said first dielectric layer.

15. The method of claim 13 further comprising forming a second photodetector on said substrate.

16. The method of claim 13, wherein forming said photodetector comprises:
forming a first dielectric layer over said region of dielectric layers;
forming openings in said region of dielectric layers, wherein said openings extend to said first dielectric layer;
forming a photodetector material in said openings; and
planarizing the surface of said first dielectric, wherein said surface is planar after said planarization.

17. The method of claim 16 further comprises removing said first dielectric layer to expose said photodetector.

18. The method of claim 13, wherein said substrate comprises a silicon on insulator material.

19. The method of claim 16, wherein said planarizing comprises a chemical mechanical polish.

20. The method of claim 16, wherein forming said photodetector material in said openings comprises a chemical vapor deposition process.
